(19) United States
(12) Patent Application Publication
(10) Pub. No.: US 2023/0087429 A1
(43) Pub. Date: Mar. 23, 2023

(54) SCALABLE COHERENT PHOTONIC INTEGRATED CIRCUIT (PIC) ARCHITECTURE

(71) Applicants: Giovanni Gilardi, Campbell, CA (US); Haijiang Yu, San Jose, CA (US); Ansheng Liu, Cupertino, CA (US); Xiaoxing Zhu, Cupertino, CA (US); Yuliya Akulova, Sunnyvale, CA (US); Raghuram Narayan, Newark, CA (US); Pierre Doussiere, Santa Clara, CA (US); Christian Malouin, San Jose, CA (US); Olufemi Dosunmu, San Jose, CA (US)

(72) Inventors: Giovanni Gilardi, Campbell, CA (US); Haijiang Yu, San Jose, CA (US); Ansheng Liu, Cupertino, CA (US); Xiaoxing Zhu, Cupertino, CA (US); Yuliya Akulova, Sunnyvale, CA (US); Raghuram Narayan, Newark, CA (US); Pierre Doussiere, Santa Clara, CA (US); Christian Malouin, San Jose, CA (US); Olufemi Dosunmu, San Jose, CA (US)

(21) Appl. No.: 18/071,337

(22) Filed: Nov. 29, 2022

Related U.S. Application Data
(60) Provisional application No. 63/414,347, filed on Oct. 7, 2022.

(51) Int. Cl. G02B 6/12; H01S 5/026; H01S 5/50

(52) U.S. Cl. CPC G02B 6/12004; H01S 5/0265; H01S 5/50; G02B 6/12007; G02B 2006/12121; G02B 2006/12159; G02B 2006/12142

(57) ABSTRACT

Embodiments herein relate to a photonic integrated circuit (PIC). The PIC may include a transmit module and a receive module. An optical port of the PIC may be coupled to the transmit module or the receive module. A semiconductor optical amplifier (SOA) may be positioned in a signal pathway between the optical port and the transmit module or the receive module. Other embodiments may be described and/or claimed.

### CROSS-REFERENCE TO RELATED APPLICATIONS

This application claims priority to U.S. Provisional Patent Application 63/414,347, filed on Oct. 7, 2022, the contents of which are incorporated herein in their entirety.

### BACKGROUND

Global data center traffic is experiencing exponential growth due to the tremendous amount of digital content being created, transmitted, and consumed. Direct detection modulation (IM-DD), a technology used in legacy data center applications, may experience one or more physical limitations that may hamper its ability to meet increasing demands in both baud rates and links length. Coherent optics may be one technology that may address these limitations. However, there may be barriers adoption of coherent optics in data centers due to higher cost, larger footprint, higher power dissipation, and potential link budget constrain.

Coherent transmission/detection has been widely used in fiber-optic communication systems, especially for long reach and metro (e.g., metropolitan area) applications. Compared to a direct detection (DD) approach, coherent technology may not only use amplitude, but may also use phase modulations and/or light polarizations. These additional options may therefore enhance transmission performance and capacity as compared to the DD approach.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates an example 400 gigabit/second (Gb/s) architecture, in accordance with various embodiments.

FIGS. 2A and 2B illustrate example 1.6 terabit/second (Tb/s) architectures based on four 400 Gb/s photonic integrated circuit (PIC) portions, in accordance with various embodiments.

FIG. 3 illustrates an example link performance comparison for several architecture configuration, in accordance with various embodiments.

FIGS. 4A, 4B, and 4C illustrate alternative example embodiments of PIC architectures, in accordance with various embodiments.

FIG. 5 illustrates an example computing system suitable for practicing various aspects of the disclosure, in accordance with various embodiments.

### DETAILED DESCRIPTION

Embodiments described herein may include apparatus, systems, techniques, or processes that are directed to scalable coherent PIC architecture.

In the following description, various aspects of the illustrative implementations will be described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. It will be apparent to one skilled in the art that embodiments of the present disclosure may be practiced without the specific details. In other instances, well-known features are omitted or simplified in order not to obscure the illustrative implementations.

In the following detailed description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

As used herein, the term “module” may refer to, be part of, or include an Application Specific Integrated Circuit (ASIC), an electronic circuit, a processor (shared, dedicated, or group), and/or memory (shared, dedicated, or group) that execute one or more software or firmware programs, a combinational logic circuit, and/or other suitable components that provide the described functionality.

As noted, the coherent transmission/detection architectures and techniques described herein may enhance transmission performance and capacity as compared to the DD approach, legacy coherent transmission/detection approaches, or legacy silicon photonic coherent transmission/detection approaches at least because the architectures/techniques described herein may enable a larger link budget without the need for external amplification. Embodiments may also enable multi-channel coherent transmission in a smaller form factor than possible in legacy approaches. Embodiments herein may provide for such techniques or approaches through the implementation of one or more semiconductor optical amplifiers (SOAs) in a silicon photonic integrated circuits (PICs). Additionally, some embodiments may include an integrated test laser to improve PIC testability at wafer level, which may further reduce product cost.

Legacy solutions may include a variety of disadvantages or drawbacks. One such drawback may relate to the presence of high loss in coherent Mach-Zehnder modulator-based transmitters, which may result in reduced link budget, require a high voltage driver, and/or require an external optical amplifier.

Another such drawback may relate to the number of channels in legacy PICs. Specifically, high density (small footprint) coherent PICs may require many optical components. Legacy solutions may only include or address single or dual channels, which may not be enough channels for some applications.

A third drawback may relate to or include test cost and/or pass/fail screening of the PICs. Specifically, a manufacturer may incur significant cost while testing or otherwise screening manufactured PICs.

Therefore, embodiments herein may relate to or include scalable transmit/receive (TRX) architecture that may be valid for operation at different optical bandwidths, for single or multiple lengths, and/or for use with different modulation formats. For example embodiments may be applicable to O-band operation, which may refer to operating wavelengths between approximately 1250 nanometers (nm) and approximately 1350 nm. Embodiments may additionally or alternatively be applicable to C-band operation, which may refer to operating wavelengths between approximately 1530 nm and approximately 1565 nm.

Specifically, embodiments may include or relate to one or more of the following:

Use of SOAs in a PIC to improve optical link performances in a transmit/receive (TRX, which may also be referred to as a “transceiver”) architecture. Specifically, the PIC may be formed of a plurality of components or elements that are positioned on a substrate (e.g., a silicon substrate). Communicative couplings between two or more of the components may be referred to as a signal pathway. One or more SOAs may be positioned within one or more signal pathways of the PIC.

Multiple tiles of TRX PICs may be used in multi-channel applications related to N×400 Gb/s operation. For example, a plurality of TRX PIC architectures may be communicatively coupled to increase the overall bandwidth of a PIC module. As one specific example, if two 400 Gb/s PIC architectures are coupled, then the overall bandwidth of the PIC module may be increased to 800 Gb/s.

In embodiments where a plurality of PIC architectures are communicatively coupled, the PICs may have or include a shared laser input and one or more SOAs to compensate for laser sharing split loss.

Similarly, in embodiments where a plurality of PIC architectures are communicatively coupled, respective receivers of the PICs may share a local oscillator (LO) signal. Signal pathways related to the respective receives may include one or more SOAs to compensate for laser sharing split loss.

Some PIC architectures may include an integrated laser to improve PIC testability at the wafer level, which may reduce component test time/product cost.

Some PIC architectures may be capable of accepting active or passive silicon (Si) dies, which may allow for highly integrated analog optical front ends for transceivers with efficient heat sinking and electromagnetic interference (EMI) shielding.

As may be recognized, embodiments may assist with resolving one or more of the above-described barriers for adoption of coherent transmission/reception in data center applications. Specifically, the introduction of one or more SOAs in signal pathways of the PIC, combined with the flexibility and scalability of the architecture, may allow the applicability to different operating wavelengths (e.g., the O-band and/or the C-band), single or multiple wavelengths, and/or different modulation formats. The use of the SOAs may also allow for link performance improvements with no increase of power budget and without increasing PIC footprint.

Embodiments may initially be described with respect to a general TRX PIC architecture capable of 400 Gb/s for coherent applications for O-band and/or C band. It will be understood that, in some embodiments, one or more components of the PIC architecture may be revised or altered dependent on which operating wavelengths the PIC is designed for, whether a single or multiple wavelength will be used, or which modulation format will be used. In other embodiments, the PIC architecture may be designed such that it is appropriate for two or more of the above considerations.

Embodiments may further be described with respect to tiling the 400 Gb/s architecture to form an N×400 Gb/s architecture, where N is an integer. It will be noted that, as used herein, 400 Gb/s is defined with a ˜60 Gbaud dual polarization (DP)-16 quadrature amplitude modulation (QAM) modulation format. The overall data throughput for the described architecture may be further scaled by increasing the baud rate to 120 Gbaud and the QAM modulation order (32QAM, 64 QAM, etc.). That is, dependent on the baud rate, modulation, and/or number of channels used, the throughput may be increased or decreased from the described 400 Gb/s.

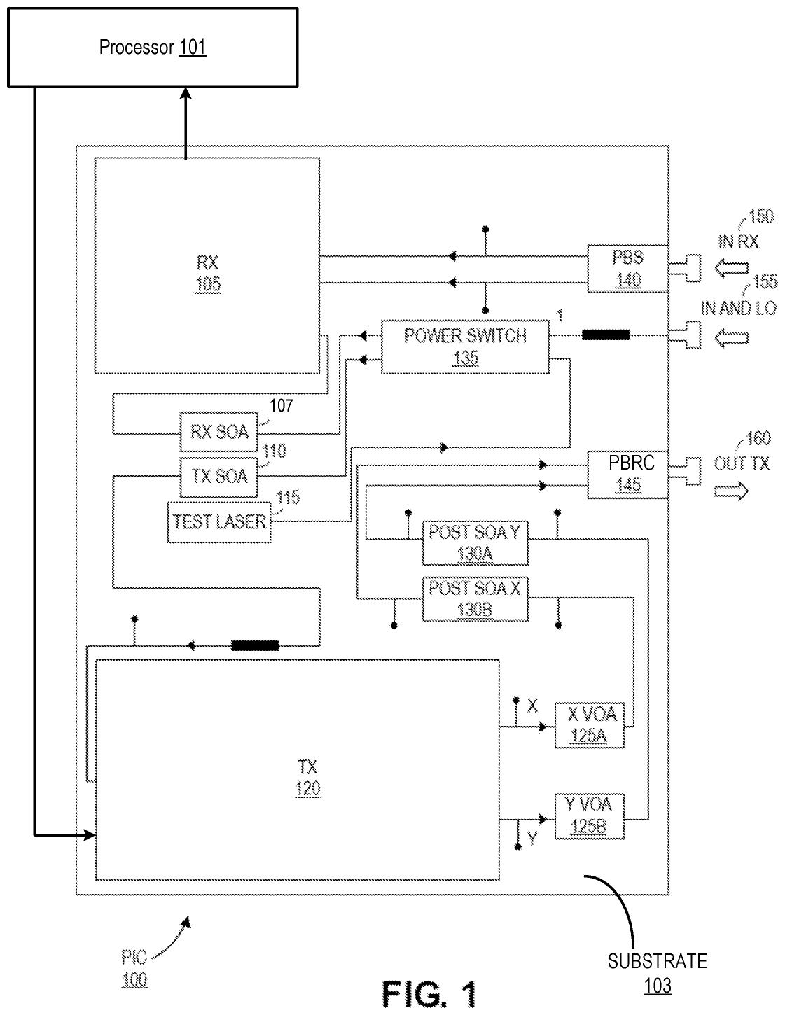

FIG. 1 provides a high level example of a PIC 100, in accordance with various embodiments herein. Specifically, the PIC 100 may provide an example of a TRX PIC architecture capable of achieving throughput of 400 Gb/s. It will be recognized that the example PIC 100 of FIG. 1—and depictions in other Figures herein—are intended as a high-level example for the purpose of discussion of embodiments of the present disclosure. Real-world or alternative implementations of the PIC 100 may include more or fewer elements, elements arranged in a location relative to other elements that is different than depicted, etc. Generally, the depicted arrows in the various signal pathways between components designate the direction that an optical and/or electrical signal propagates.

The PIC 100 may include a receive (RX) module 105 positioned on a substrate 103. The RX module 105 may include logic to receive and process an optical signal received from a transmit source that is remote to the PIC 100. For example, the optical signal may be received at a receive optical port 150 of the PIC 100 that is communicatively coupled with the RX module 105, as shown in FIG. 1. As may be seen in FIG. 1, the received optical signal may be a modulated optical signal, which is represented in FIG. 1 as having an two signal pathways between the receive optical port 150 and the RX module 105. Respective ones of the signal pathways may carry optical signals.

The substrate 103 may be a substrate such as a silicon substrate. In some embodiments, the substrate may have one or more layers, traces, vias, etc. Unless described differently below, the various elements of the substrate are not shown in FIG. 1 for the sake of clarity and lack of clutter

As used herein, the term “signal pathway” may refer to a communicative coupling between two elements of the PIC 100 (e.g., by way of a trace or some other communicative coupling). A data, electrical, and/or optical signal may propagate through the PIC between two components along a signal pathway as depicted in FIG. 1. It will be understood that different signal pathways of FIG. 1 are not explicitly enumerated for the sake of clarity and lack of clutter of the Figure, but, where necessary, may be described with respect to the two components of the PIC 100 that are coupled by such a signal pathway.

The logic of the RX module 105 may be or include, for example, a demodulator to demodulate the signal, a processor, a discrete signal processor (DSP), a transimpedance amplifier (TIA), etc. In some embodiments, the RX module 105 may be coupled with other logic such that the RX module 105 may extract data from a received optical signal (or a portion thereof as described below with respect to the polarization beam splitter (PBS) 140) and output the data to another element of an electronic device of which the PIC 100 is a part. Such element may be, for example a processor such as processor 101. Specifically, the processor 101 may be a processor such as a central processing unit (CPU), a core of a multi-core processor, or some other type of processor or logic. In other embodiments, the processor 101 may be another type of element of an electronic device such as a memory or some other element. In some embodiments, the RX module 105 (or elements thereof) may be referred to as an intradyne coherent receiver (ICR).

Generally, the functioning of the RX module 105 is only discussed at a high level herein, as the function of such an RX module 105 may be dependent upon the specific implementation of such a module. It will be recognized that various alternative implementations may be possible, and the specific functioning of such a module may be readily apparent to one of skill in the art.

In some embodiments the PIC 100 may include the PBS 140 positioned in the signal pathway between the RX module 105 and the receive optical port 150. In embodiments, the PBS 140 may be a device that has a single input port and two output ports (e.g., the receive optical port 150 and the two output ports that form the two depicted signal pathways between the PBS 140 and the RX module 105). The PBS 140 receive as input an optical signal that has both transverse electric (TE) and transverse magnetic (TM) components. The PBS 140 may then separate the TE and TM components of the input signal and output the TE component of the input signal along one of the depicted signal pathways. The PBS 140 may further rotate the TM component to generate a second TE component that is then output along the other one of the depicted signal pathways. In this way, a single optical signal may be received at the receive optical port 150, and the single optical signal may include two separate data signals that may be split by the PBS 140 for processing by the RX module 105.

The PIC 100 may further include a transmit (TX) module 120 on the substrate 103. The transmit (TX) module 120 may additionally or alternatively be referred to as, or include, a dual polarization in-phase quadrature (DP-IQ) modulator. Specifically, the TX module 120 may be configured to receive a reference optical signal (e.g., the reference optical signal received on the reference signal port 155 as described below) and a data signal. The data signal may be, for example, a data signal received from the processor 101. The TX module 120 may include a modulator that is configured to modulate the reference optical signal based on the received data signal to generate a modulated data signal, and then output the modulated data signal for transmission from the PIC 100 at the transmit optical port 160. Similarly to the RX module 105, the TX module 120 may include one or more components or elements such as the above-described modulator, a processor, a memory, and/or some other component.

Similarly to the RX module 105, the TX module 120 is described herein at a high-level, as the functioning of such a TX module 120 may be dependent on the specific implementation of such a module. The specific characteristics and functions of such a TX module 120 may be apparent to one of skill in the art.

As may be seen, the TX module 120 may output a two optical signals. One of the optical signals may be output along the signal pathway between the TX module 120 and the transmit optical port 160 designated with an “X,” and the other optical signal may be output along the signal pathway. Both of the output optical signals may be TE-polarized optical signals.

A polarization beam rotator combiner (PBRC) 145 may be configured to rotate at least one of the received optical signals on the X pathway or the Y pathway (e.g., rotation by 90 degrees) to convert the TE signal into a TM signal, and then combine the respective TE and TM signals into a single optical signal that that is output from the optical transmit port 160.

Generally, the specific actions or configurations of the PBS 140 and the PBRC 145, and how they modify the polarization of one or more signals, split one or more signals, or combine one or more signals may vary based on the specific implementations of such elements, and different variations will be readily apparent to one of skill in the art.

As may be seen, the PIC 100 may further include one or more variable optical attenuators (VOAs) such as VOAs 125A and 125B. The VOAs 125A/125B may be electro-optical components that may variably attenuate the optical signal based on application of power to the VOAs.

In embodiments, the reference optical signal may be provided to the PIC 100 at a reference optical port 155. In some embodiments, the reference optical signal may be referred to as a “local oscillator” (“LO”) signal. Specifically, an reference optical signal with a fixed (i.e., non-variable) wavelength (and, hence, a fixed frequency) may be provided at the reference optical port 155. Such a reference optical signal may be used by the RX module 105 to demodulate a received modulated optical signal. Similarly, the reference optical signal may be used by the TX module 120 to modulate a data signal such as a data signal that may be received from processor 101.

In some embodiments, the wavelength of the reference optical signal may be approximately 1310 nm if the PIC 100 is operating in the O-band, and approximately 1550 nm if the PIC 100 is operating in the C-band, although in other embodiments the wavelength of the reference optical signal may be different based on factors such as the components used in the electrical device of which the PIC 100 is a part, the components used in the PIC 100, etc.

The PIC 100 may further include a power switch 135 that is in a signal pathway between the reference optical port 155 and the RX module 105. The power switch 135 may further be positioned in the signal pathway between the reference optical port 155 and the TX module 120. Generally, the power switch 135 may be switch or signal splitter that is configured to split a signal such as the reference optical signal or an optical signal received from a test laser 115 between the RX module 105 and the TX module 120. In some embodiments, the signal may be split according to a ratio (e.g., some amount of the signal may be directed toward the RX module 105 while a remaining amount of the signal may be directed toward the TX module 120). In some embodiments, the ratio may be variable. For example, the power switch 135 may be electrically controlled and a controller (not shown) may vary the amount that a signal goes to the RX module 105 or the TX module 120. In other embodiments, the power switch 135 may be static such that the splitting ratio is non-variable.

The PIC 100 may further include one or more SOAs on the substrate 103 as shown in FIG. 1. For example the PIC 100 may include a RX SOA 107 located in a signal path between the power switch 135 and the RX module 105. The PIC 100 may additionally/alternatively include a TX SOA 110 located in a signal path between the power switch 135 and the TX module 120. The PIC 100 may additionally/alternatively include SOAs 130A and 130B, which may respectively be located in the signal paths between the TX module 120 and the optical transmit port 160. As may be seen, the SOA 130B, which is referred to as the “Post SOA X”, may be located in the X signal pathway, while the SOA 130A, which is referred to as “Post SOA Y” may be located in the Y signal pathway.

The SOAs 107/110/130A/130B may be configured to amplify the signal in the various signal pathways. As noted above, a legacy PIC using coherent transmission or detection may experience laser sharing split loss, which may result in a weakened optical signal. By positioning the various SOAs in the various signal pathways, this split loss may be at least partially compensated for by amplifying the optical signal. In this way, a relatively compact and flexible PIC 100 may be formed without requiring, e.g., an external amplifier.

In some embodiments, the PIC 100 may additionally or alternatively include a test laser 115. The test laser 115 may be coupled with the input of the power switch 135 as shown in FIG. 1. Generally, in legacy embodiments, a plurality of PICs may be produced on a single wafer. Due to the large number of components on the PIC, it may be hard to access and validate the electro-optical functionalities of any single components and the overall functionalities of the PIC 100. A pass/fail full characterization would require alignment of an external laser, which in legacy architectures may not be possible unless the PIC is not extracted from the wafer (e.g., through wafer dicing and PIC preparation).

However, in embodiments herein, the PIC 100 may include the test laser 115 on-board the PIC 100. The test laser 115 may be used to generate an optical test signal for the PIC 100, which may then allow for testing of the PIC 100. Notably, such an optical test signal may be usable without the need for first dicing the wafer or coupling the PIC under test to a separate test laser. Therefore, the test process may be significantly expedited and result in a lower overall cost of manufacture.

Specifically, the test laser 115 may allow for characterization of the TX module 120 and the RX module 105 at the wafer level. Specifically, the test laser 115 may be turned-on, and optical monitor power may be used for electro-optical characterization of the TX and RX modules.

An electrical characterization test may be done at the wafer level by directly monitoring or probing components of interest. For example, in FIG. 1, the electro-optical characteristics of the TX module 120 and the RX module 105 may be evaluated at the wafer level by landing a multipin probe on electrical pads. The probe may then be used to both control the test laser 115 and read the optical signal output by the PIC 100. More specifically, the probe may cause the test laser 115 to provide a test optical signal. The probe may also be coupled to the transmit optical port 160. The strength of the signal transmitted by the PIC may then be monitored by the probe to identify, for example, that the waveguide is not damaged and various elements of the PIC are working correctly. It will be noted that the test laser 115 may be coupled to the input of the power switch 135 so that the test laser 115 may be directed towards the RX module 105, the TX module 120, or both, dependent on how the test is to be structured.

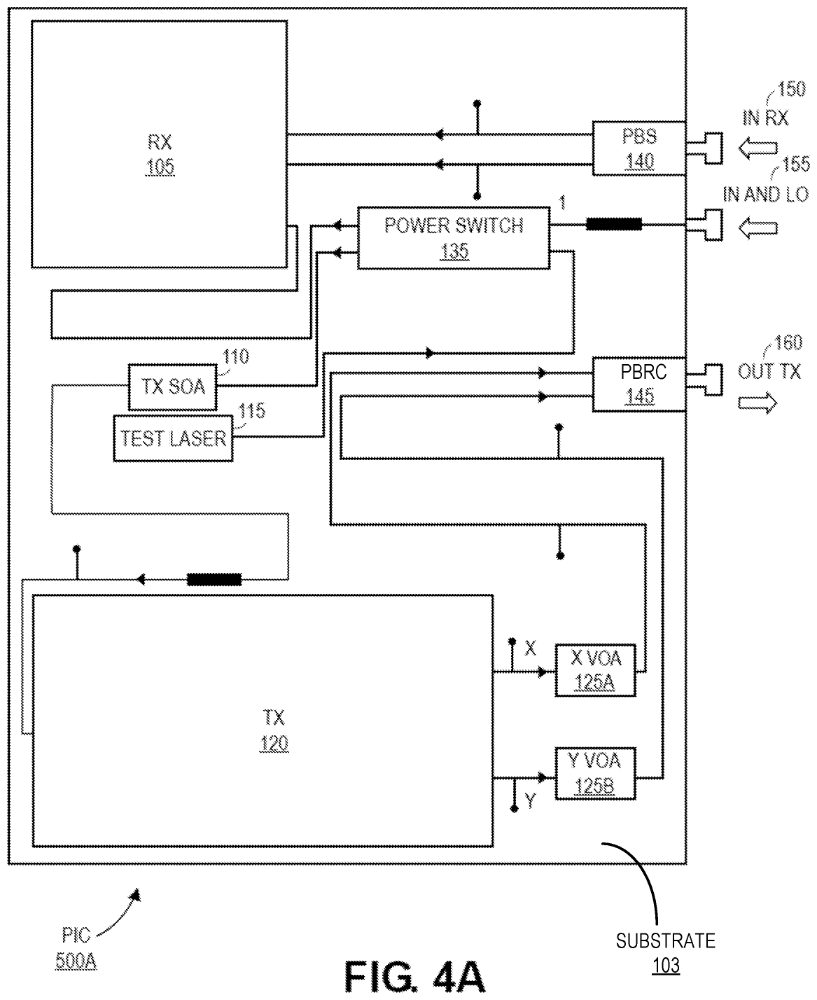

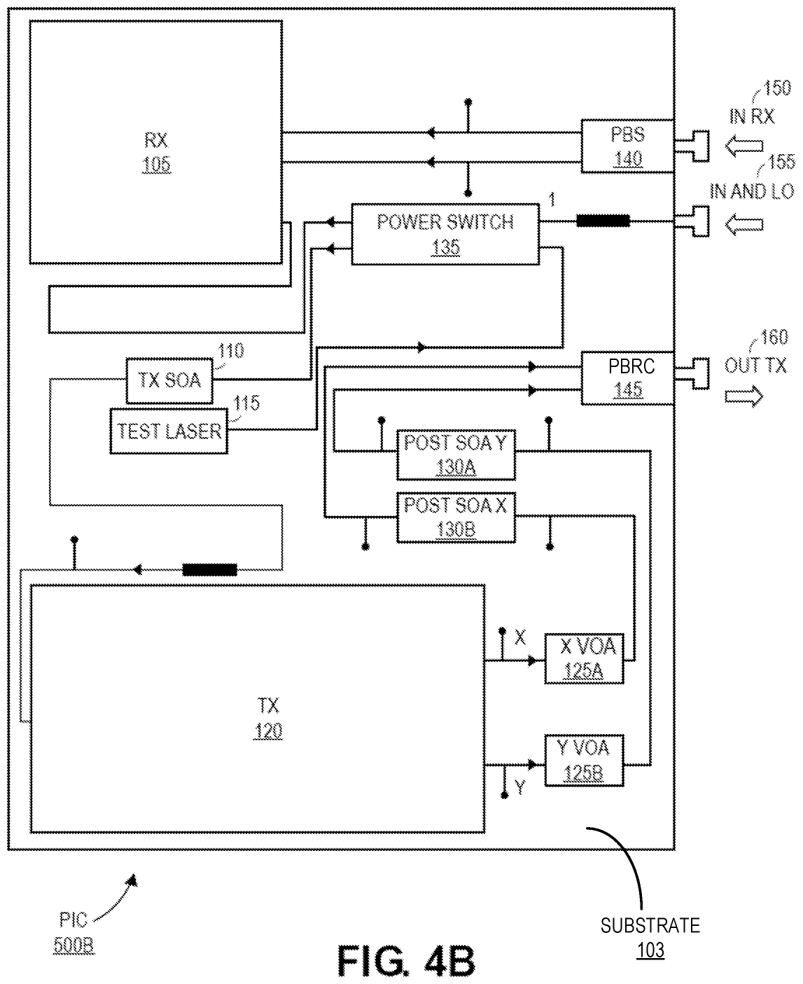

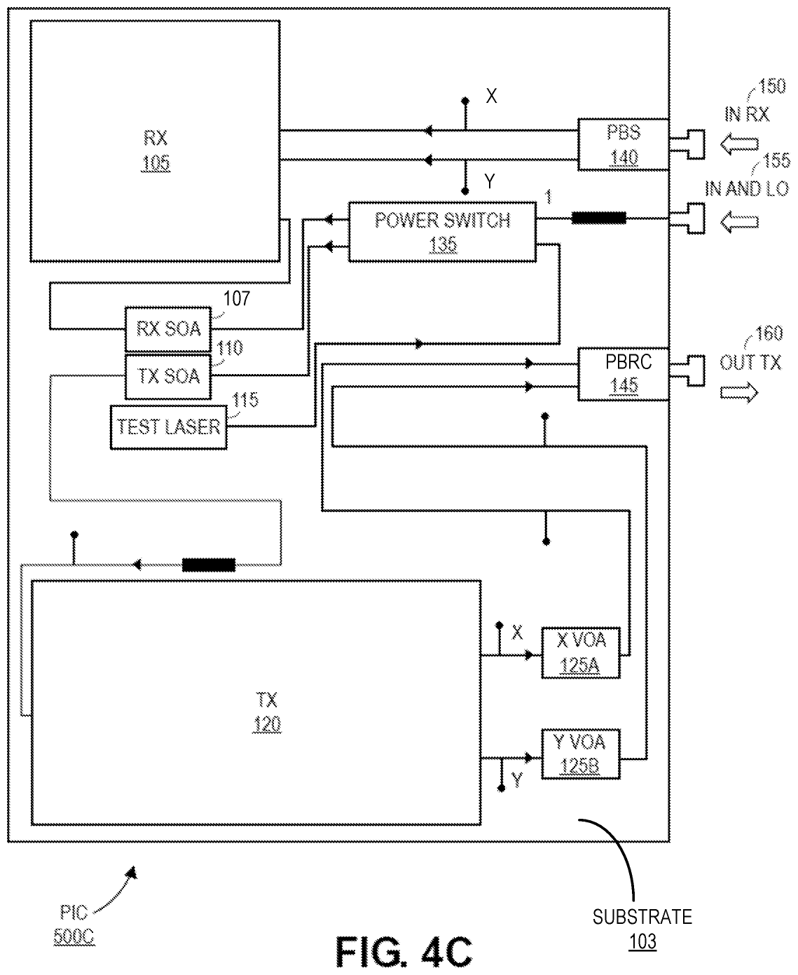

It will be understood that the architecture depicted in FIG. 1 may be modified, for example by removing one or more of the components listed above. Examples of such modification may be depicted and discussed below with respect to FIGS. 4A, 4B, and 4C. However, such modifications may still result in a functional PIC having different performances and tailored for a specific application defined by a) transmitted power requirements, and b) PIC overall power consumption.

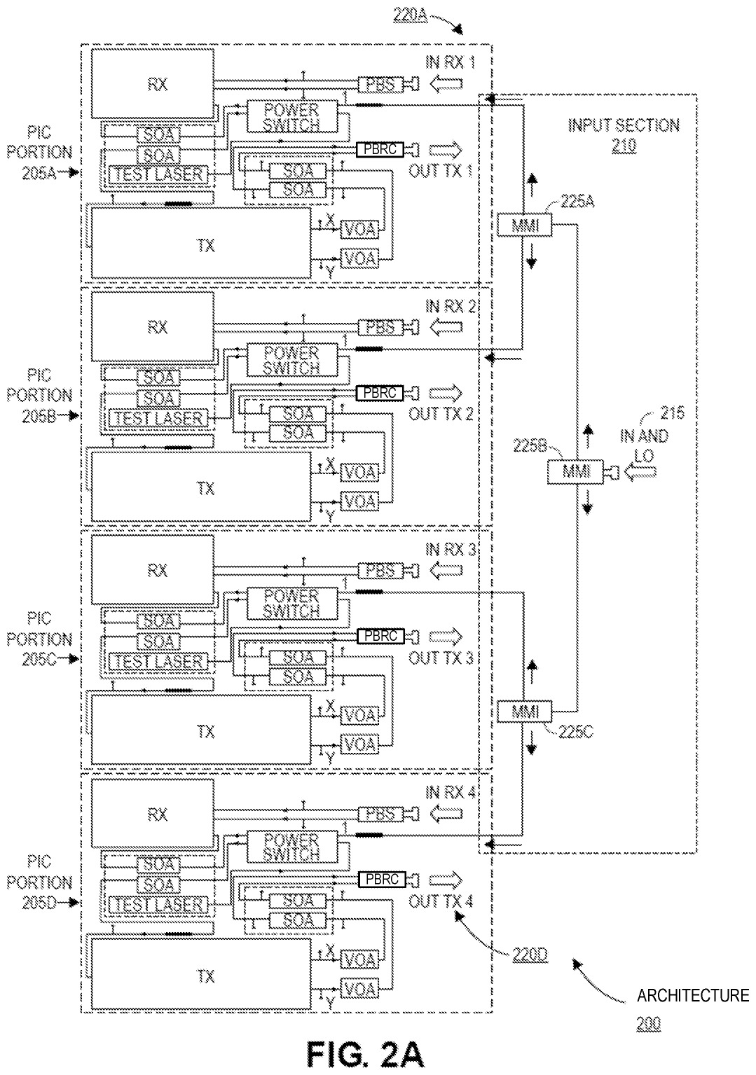

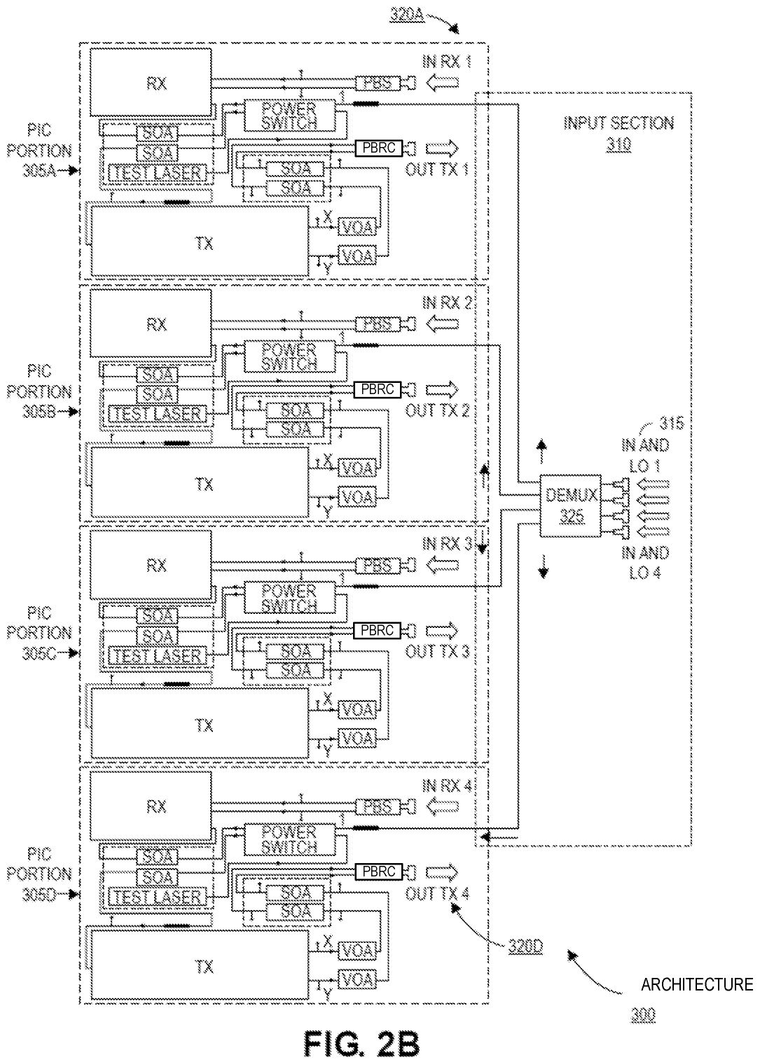

As previously noted, FIG. 1 may be understood to depict a PIC 100 with a throughput of 400 Gb/s. However, in some embodiments the PIC 100 may be viewed as a “building block” for an extended architecture that may have an increased throughput (e.g., N×400 Gb/s where N is an integer). FIGS. 2A and 2B depict an example architecture that includes a plurality of PICs in an N×400 Gb/s architecture where N=4. As a result, the architecture of FIG. 2A or 2B may have a throughput of approximately 1.6 terabytes per second (Tb/s). It will be understood that a 400 Gb/s PIC is used herein as one example of such a PIC, and in other embodiments one or more of the depicted PICs may have a different throughput (e.g., based on alteration of the modulation, the baud rate, etc.). In some embodiments different ones of the depicted PICs may each have the same throughput as one another, while in other embodiments one or more of the depicted PICs may have a throughput different than that of another one of the depicted PICs.

FIG. 2A illustrates an example 1.6 Tb/s architecture 200 based on four 400 Gb/s PIC portions 205A, 205B, 205C, and 205D (collectively, PIC portions 205), in accordance with various embodiments.

As may be seen, respective ones of the PIC portions 205 may be similar to, and share one or more elements with, PIC 100 of FIG. 1. Specifically, as may be seen, respective PIC portions 205 may have respective receive and transmit optical ports. For example, PIC portion 205A may have receive and transmit optical ports 220A, and PIC portion 205D may have receive and transmit optical ports 220D. However, as may further be seen, the PIC portions 205 may be coupled with an input section 210. The input section 210 may include one or more multimode interferometers (MMIs) 225A, 225B, and 225C. The MMI 225B may be coupled with a reference optical port 215, which may be similar to reference optical port 155. The MMI 225B may receive a reference optical signal from the reference optical port 215, and split the received signal as shown in FIG. 2. MMI 225A may receive at least part of the split signal and further split the signal between PIC portions 205A and 205B, while MMI 225C may similarly further split the signal between PIC portions 205C and 205D. It will be noted that the specific configuration of the depicted input section 210 is depicted as an “MMI-tree” type configuration, and other embodiments may have a different configuration or use different mechanisms to split the received optical signal.

In this way, a single reference optical signal may be routed (via the input section 210) to four PIC portions 205. The resultant architecture 200 may have four independent receive optical ports and four independent transmit optical ports (e.g., a receive and transmit optical port at each of the PIC portions 205), which may allow for a significant increase in throughput of the architecture 200.

FIG. 2B illustrates an alternative example 1.6 Tb/s architecture 300 based on four 400 Gb/s PIC portions 305A, 305B, 305C, and 305D (collectively, PIC portions 305), in accordance with various embodiments.

As may be seen, respective ones of the PIC portions 305 may be similar to, and share one or more elements with, PIC 100 of FIG. 1. Specifically, as may be seen, respective PIC portions 305 may have respective receive and transmit optical ports. For example, PIC portion 305A may have receive and transmit optical ports 320A, and PIC portion 305D may have receive and transmit optical ports 320D.

The PIC portions 305 may be coupled with an input section 310. The input section 310 may include a demultiplexer 325 that is coupled with a plurality of reference optical ports 315. Specifically, as shown in FIG. 2B, the input section 310 may include four separate reference optical ports at 315. Respective ones of the reference optical ports 315 may be configured to receive a reference optical signal with a different wavelength. For example, one of the ports at 315 may receive a reference optical signal with a wavelength of approximately 1270 nm. Another of the ports at 315 may receive an optical signal with a wavelength of approximately 1290 nm, etc. The demultiplexer 325 may be configured to identify the wavelength of the reference optical signal and route the reference optical signal to the appropriate PIC portion 305. For example, PIC portion 305A may receive, and use, the reference optical signal with the wavelength of approximately 1270 nm. PIC portion 305D may receive, and use, the reference optical signal with the wavelength of approximately 1290 nm.

It will be noted that the device of FIG. 2A may operate with one single wavelength, while the device of FIG. 2B may operate with multiple wavelengths. In both cases, the input sections 210/310 may be designed on the same substrate (e.g., substrate 103) as the various PIC portions 205/305. It will also be noted that the depicted architectures 200/300 may be compatible with wavelengths in the O-band and the C-band. It will also be noted that the specific wavelengths, or number of ports or PIC portions, are described herein for the sake of example, and other embodiments or implementations may use different reference wavelengths, include more or fewer PIC portions, more or fewer ports, etc.

The PIC 100 and/or the architectures 200/300 described herein may resolve one or more of the above described disadvantages of legacy architectures. For example, SOAs such as SOAs 107/110/130A/103B may be placed in several locations on PIC. The SOAs may mitigate or eliminate the need of high power input laser by providing compensation for split-loss as the signal propagates through the PIC 100 and/or architectures 200/300.

The SOAs may further reduce or eliminate the need for an amplifier at the output of the PIC 100 such as an EDFA (Erbium-Doped Fiber Amplifier) or PDFA (Praseodymium-Erbium-Doped Fiber Amplifier). Typically, such amplifiers at the output of a PIC may have been necessary to mitigate the optical power loss of the optical signal due to routing the optical signal through the PIC 100. As a result, such amplifiers (e.g., the EDFA and/or PDFA) may have been required to restore the attenuated power signal. However, the SOAs may help resolve this issue by boosting the optical signal in the PIC itself, which may mitigate the need for off-PIC amplifiers such as the EDFA and/or PDFA.

The SOAs may also allow for a higher link optical power margin (e.g., a higher variance in the amount of optical power that the PIC may receive). Therefore, the SOAs may allow for a lower overall manufacturing cost by relaxing the need for certain components at an input of the PIC, an output of the PIC, or coupled to the PIC to be manufactured within specific specifications or tolerances.

The SOAs may also reduce or eliminate the degree of voltage swing experienced by various components of the PIC as the optical signal propagates through the PIC by helping to increase the signal level on the PIC. As such, a voltage driver coupled to the PIC may be un-necessary, which will reduce the overall power consumption of the PIC.

More generally, the effect of SOA utilization in the signal pathways of the PIC may enable low cost, multi-channels coherent solutions that may be appropriate in data center applications.

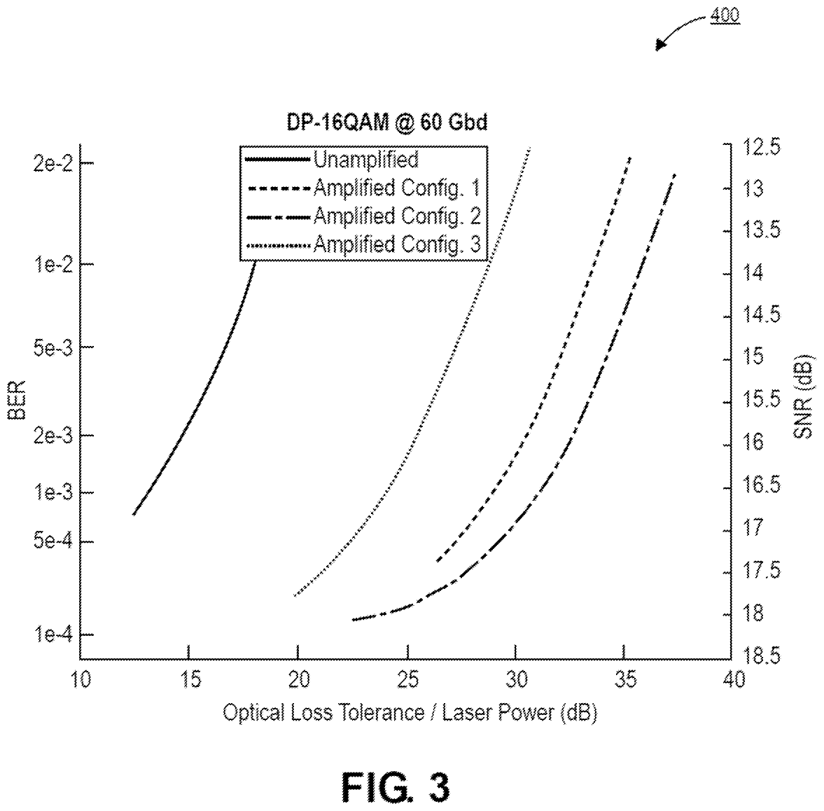

FIG. 3 shows an example link performance for four different cases. The benchmark (indicated in the legend as “unamplified”) is an example of the PIC 100, but without any SOAs.

An alternative configuration, indicated in the legend of FIG. 3 as “Amplified Config. 1” may correspond to PIC 500A of FIG. 4A. As may be seen in FIG. 4A, only the TX SOA 110 may be present. Other SOAs such as SOAs 107, 130A, and 130B may not be present. This configuration may be desirable

An alternative configuration, indicated in the legend of FIG. 3 as “Amplified Config. 2” may correspond to PIC 500B of FIG. 4B. As may be seen in FIG. 4B, the TX SOA 110 and SOAs 130A/130B may present. SOA 107 may not be present.

An alternative configuration, indicated in the legend of FIG. 3 as “Amplified Config. 3” may correspond to PIC 500C of FIG. 4C. As may be seen in FIG. 4C, the TX SOA 110 and RX SOA 107 may be present, but SOAs 130A/130B may not be present.

As may be seen in FIG. 3, each of the configurations depicted in FIGS. 4A/4B/4C may have significantly higher loss tolerance/laser power than the unamplified configuration. Specifically, FIG. 3 may be based on the use of a Dual-Polarization 16 QAM (DP-16QAM) modulation format at a symbol rate of 60 Gbaud. The bit error rate (BER) may be calculated as a function of the optical loss added during transmission between two PICs (e.g., between the optical transmit port 160 of one PIC to the optical receive port 150 of another PIC). In some use cases, such transmission may be over a distance that is on the order of several kilometers.

The three amplified cases (corresponding to FIGS. 4A-4C) outperform the unamplified case. Specifically, the system tolerance to optical loss (normalized to the laser power) is 10 to 20 dB more for the amplified configurations than the unamplified configuration. As a result, it will be recognized that the various embodiments of the PIC herein (e.g., PIC 100 or some other PIC or architecture depicted herein) may allow for use cases of communications links that are significantly longer than those allowed by legacy coherent transmission or DD implementations.

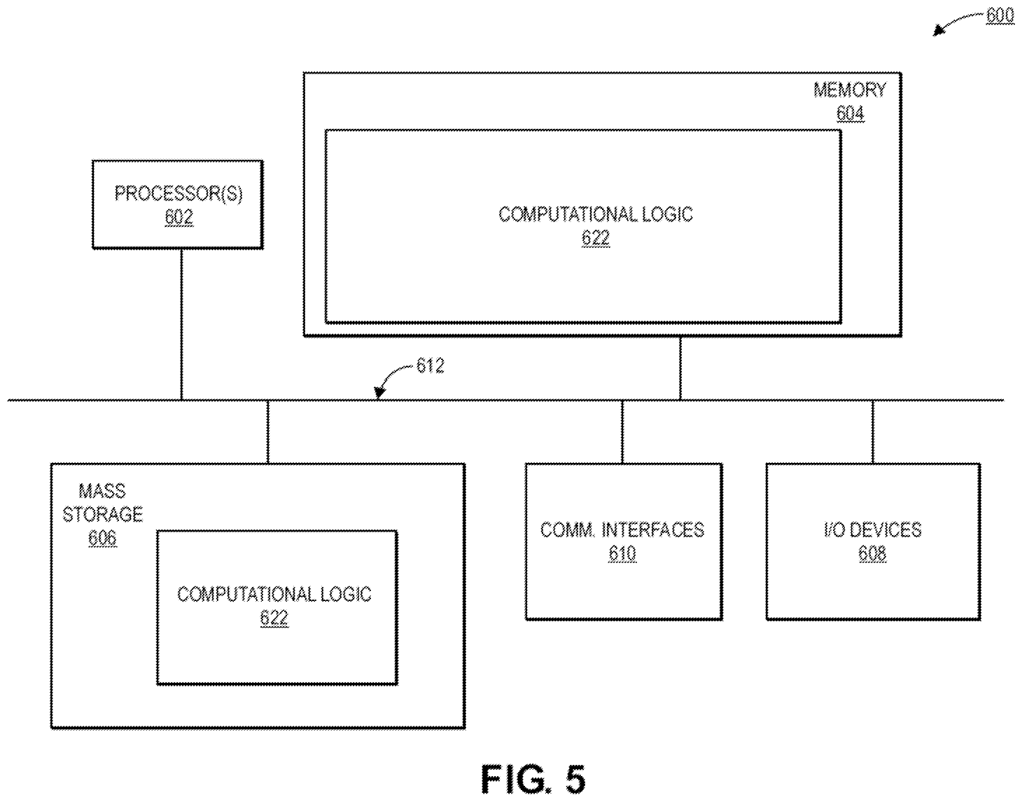

FIG. 5 illustrates an example computing device 500 suitable for use to practice aspects of the present disclosure, in accordance with various embodiments. For example, the example computing device 500 may include or be suitable to implement the functionalities associated with any of FIGS. 1-4, and/or some other example, embodiment, or Figure described herein.

As shown, computing device 500 may include one or more processors 502, each having one or more processor cores, and system memory 504. The processor 502 may be similar to, for example, processor 101. The processor 502 may include any type of unicore or multi-core processors. Each processor core may include a central processing unit (CPU), and one or more level of caches. The processor 502 may be implemented as an integrated circuit. The computing device 500 may include mass storage devices 506 (such as diskette, hard drive, volatile memory (e.g., dynamic random access memory (DRAM)), compact disc read only memory (CD-ROM), digital versatile disk (DVD) and so forth). In general, system memory 504 and/or mass storage devices 506 may be temporal and/or persistent storage of any type, including, but not limited to, volatile and non-volatile memory, optical, magnetic, and/or solid state mass storage, and so forth. Volatile memory may include, but not be limited to, static and/or dynamic random access memory. Non-volatile memory may include, but not be limited to, electrically erasable programmable read only memory, phase change memory, resistive memory, and so forth.

The computing device 500 may further include input/output (I/O) devices 508 such as a display, keyboard, cursor control, remote control, gaming controller, image capture device, one or more three-dimensional cameras used to capture images, and so forth, and communication interfaces 510 (such as network interface cards, modems, infrared receivers, radio receivers (e.g., Bluetooth), and so forth). I/O devices 508 may be suitable for communicative connections with three-dimensional cameras or user devices. In some embodiments, I/O devices 508 when used as user devices may include a device necessary for implementing the functionalities of receiving an image captured by a camera.

The communication interfaces 510 may include communication chips (not shown) that may be configured to operate the device 500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 510 may operate in accordance with other wireless protocols in other embodiments.

The above-described computing device 500 elements may be coupled to each other via system bus 512, which may represent one or more buses. In the case of multiple buses, they may be bridged by one or more bus bridges (not shown). Each of these elements may perform its conventional functions known in the art. In particular, system memory 504 and mass storage devices 506 may be employed to store a working copy and a permanent copy of the programming instructions implementing the operations and functionalities associated with any of FIGS. 1-4, and/or some other example, embodiment, or Figure described herein, generally shown as computational logic 522. Computational logic 522 may be implemented by assembler instructions supported by processor(s) 502 or high-level languages that may be compiled into such instructions.

The permanent copy of the programming instructions may be placed into mass storage devices 506 in the factory, or in the field, though, for example, a distribution medium (not shown), such as a compact disc (CD), or through communication interfaces 510 (from a distribution server (not shown)).

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

### Examples

Example 1 relates to the possibility to integrate SOA (to improve link performances) and laser in SiPh. The presence of laser described herein may be used to enable the on-chip test.

Example 2 relates to a scalable and flexible coherent PIC architecture for 0 and C band applications operating with single or multiple wavelengths and operating with different modulation formats.

Example 3 relates to a photonic integrated circuit (PIC) comprising: a transmit module; a receive module; an optical port coupled to one of the transmit module and the receive module; and a semiconductor optical amplifier (SOA) positioned in a signal pathway between the optical port and the one of the transmit module and the receive module.

Example 4 relates to the PIC of example 3, and/or some other example herein, wherein the receive module is an intradyne coherent receiver (ICR).

Example 5 relates to the PIC of any of examples 3-4, and/or some other example herein, wherein the transmit module includes a dual polarization (DP) in-phase quadrature (IQ) modulator.

Example 6 relates to the PIC of any of examples 3-5, and/or some other example herein, wherein the optical port is a input port configured to receive an optical signal from a transmit source, and wherein the signal pathway is between the optical port and the receive module.

Example 7 relates to the PIC of any of examples 3-5, and/or some other example herein, wherein the optical port is an output port configured to transmit a modulated optical signal from the PIC, and wherein the signal pathway is between the transmit module and the optical port.

Example 8 relates to the PIC of example 7, and/or some other example herein, wherein the signal pathway includes a first signal pathway between the optical port and the transmit module and a second signal pathway between the optical port and the transmit module, and wherein the SOA is a first SOA positioned in the first signal pathway, and the PIC further includes a second SOA positioned in the second signal pathway.

Example 9 relates to the PIC of any of examples 3-5, and/or some other example herein, wherein the optical port is an optical port configured to receive an optical data signal with a pre-determined wavelength, and wherein the signal pathway includes a first signal pathway between the optical port and the receive module, and a second signal pathway between the optical port and the transmit module, and wherein the SOA is in one of the first signal pathway and the second signal pathway.

Example 10 relates to the PIC of example 9, and/or some other example herein, further comprising a power switch positioned between the optical port and the transmit module, and between the optical port and the receive module, wherein the power switch is configured to receive the optical data signal and output at least a portion of the optical data signal between one of the first signal pathway and the second signal pathway.

Example 11 relates to the PIC of example 10, and/or some other example herein, wherein the PIC further comprises a test laser configured to output a test optical signal to the power switch.

Example 12 relates to the PIC of example 9, and/or some other example herein, wherein the SOA is a first SOA that is in the first signal pathway, and wherein the PIC further comprises a second SOA that is in the second signal pathway.

Example 13 relates to an apparatus comprising a plurality of communicatively-coupled ones of the PIC of any of examples 3-12, and/or some other example herein.

Example 14 relates to a photonic integrated circuit (PIC) comprising: a transmit module; a receive module; an optical port coupled to the transmit module or the receive module; and a semiconductor optical amplifier (SOA) positioned in a signal pathway between the optical port and the transmit module or the receive module.

Example 15 relates to the PIC of example 14, and/or some other example herein, wherein the transmit module, the receive module, and the SOA are positioned on a same substrate as one another.

Example 16 relates to the PIC of any of examples 14-15, and/or some other example herein, wherein the receive module is an intradyne coherent receiver (ICR).

Example 17 relates to the PIC of any of examples 14-16, and/or some other example herein, wherein the transmit module includes a dual polarization (DP) in-phase quadrature (IQ) modulator.

Example 18 relates to the PIC of any of examples 14-17, and/or some other example herein, wherein the optical port is a transmit optical port configured to transmit a modulated optical signal from the PIC, and wherein the signal pathway is between the transmit module and the transmit optical port.

Example 19 relates to the PIC of example 18, and/or some other example herein, wherein the signal pathway includes a first signal pathway between the transmit optical port and the transmit module and a second signal pathway between the transmit optical port and the transmit module, and wherein the SOA is a first SOA positioned in the first signal pathway, and the PIC further includes a second SOA positioned in the second signal pathway.

Example 20 relates to the PIC of any of examples 14-17, and/or some other example herein, wherein the optical port is a reference optical port configured to receive an optical reference signal with a fixed wavelength, and wherein the signal pathway includes a first signal pathway between the reference optical port and the receive module, and a second signal pathway between the reference optical port and the transmit module, and wherein the SOA is in the first signal pathway or the second signal pathway.

Example 21 relates to the PIC of example 20, and/or some other example herein, further comprising a power switch positioned between the reference optical port and the transmit module, and between the reference optical port and the receive module, wherein the power switch is configured to receive the reference optical signal and output at least a portion of the reference optical signal between the first signal pathway or the second signal pathway.

Example 22 relates to the PIC of example 21, and/or some other example herein, wherein the PIC further comprises a test laser configured to output a test optical signal to the power switch.

Example 23 relates to the PIC of example 20, and/or some other example herein, wherein the SOA is a first SOA that is in the first signal pathway, and wherein the PIC further comprises a second SOA that is in the second signal pathway.

Example 24 relates to an electronic device comprising: a first photonic integrated circuit (PIC) portion that includes a first transmit module, a first receive module, a first receive optical port, a first transmit optical port, a first reference optical port, and a first semiconductor optical amplifier (SOA) positioned in a first signal pathway between: the first transmit module or the first receive module; and the first receive optical port, the first reference optical port, or the first transmit optical port; and a second PIC portion that includes a second transmit module, a second receive module, a second receive optical port, a second transmit optical port, and a second SOA positioned in a second signal pathway between: the second transmit module or the second receive module; and the second receive optical port, the second reference optical port, or the second transmit optical port.

Example 25 relates to the electronic device of example 24, and/or some other example herein, wherein the first PIC portion and the second PIC portion are on a same substrate as each other.

Example 26 relates to the electronic device of any of examples 24-25, and/or some other example herein, wherein the first reference optical port and the second reference optical port are communicatively coupled with a multimode interferometer (MMI).

Example 27 relates to the electronic device of example 26, and/or some other example herein, wherein the MMI is positioned in a third signal pathway between a third reference optical port and the first reference optical port, and wherein the MMI is further positioned in a fourth signal pathway between the third reference optical port and the second reference optical port.

Example 28 relates to the electronic device of any of examples 24-25, and/or some other example herein, wherein the first reference optical port and the second reference optical port are communicatively coupled with a demultiplexer configured to: demultiplex a plurality of reference optical signals signal to generate a first reference optical signal and a second reference optical signal; output the first reference optical signal to the first reference optical port; and output the second reference optical signal to the second reference optical port.

Example 29 relates to a method of forming a photonic integrated circuit (PIC), wherein the method comprises: coupling a transmit module to a substrate of the PIC; coupling a receive module to the substrate; communicatively coupling an optical port of the PIC to the transmit module or the receive module to form a signal pathway between the optical port and the transmit module or the receive module; and positioning a semiconductor optical amplifier (SOA) in the signal pathway on the substrate.

Example 30 relates to the method of example 29, and/or some other example herein, wherein the receive module is an intradyne coherent receiver (ICR).

Example 31 relates to the method of any of examples 29-30, and/or some other example herein, wherein the transmit module includes a dual polarization (DP) in-phase quadrature (IQ) modulator.

Example 32 relates to the method of any of examples 29-31, and/or some other example herein, wherein the optical port is a transmit optical port configured to transmit a modulated optical signal from the PIC, and wherein the signal pathway is between the transmit module and the transmit optical port.

Example 33 relates to the method of any of examples 29-31, and/or some other example herein, wherein the optical port is a reference optical port configured to receive an reference optical signal with a fixed wavelength, and wherein the signal pathway includes a first signal pathway between the reference optical port and the receive module, and a second signal pathway between the reference optical port and the transmit module, and wherein the SOA is in the first signal pathway or the second signal pathway.

Example 34 relates to a photonic integrated circuit (PIC) comprising: a transmit module positioned on a substrate of the PIC; a receive module positioned on the substrate; a reference optical port communicatively coupled with the transmit module by a first signal pathway, wherein the reference optical port is further communicatively coupled with the receive module by a second signal pathway; a transmit optical port communicatively coupled with the transmit module by a third signal pathway, wherein the transmit optical port is configured to transmit a first optical signal from the PIC; a receive optical port communicatively coupled with the receive module by a fourth signal pathway, wherein the receive optical port is configured to receive a second optical signal; and a first semiconductor optical amplifier (SOA) positioned on the substrate, wherein the first SOA is in the first signal pathway.

Example 35 relates to the PIC of example 34, and/or some other example herein, wherein the receive module includes an intradyne coherent receiver (ICR).

Example 36 relates to the PIC of any of examples 34-35, and/or some other example herein, wherein the transmit module includes a dual polarization (DP) in-phase quadrature (IQ) modulator.

Example 37 relates to the PIC of any of examples 34-36, and/or some other example herein, further comprising a power switch in the first and second signal pathways, wherein the power switch is to receive as input an reference optical signal from the reference optical port, and wherein the power switch is further to output at least a portion of the reference optical signal to the first signal pathway or the second signal pathway.

Example 38 relates to the PIC of example 37, and/or some other example herein, wherein the first SOA is in the first signal pathway between the power switch and the transmit module.

Example 39 relates to the PIC of example 37, and/or some other example herein, wherein the PIC further comprises a test laser configured to output a test optical signal to the power switch.

Example 40 relates to the PIC of any of examples 34-39, and/or some other example herein, wherein the PIC further comprises a second SOA positioned on the substrate, wherein the second SOA is in the second signal pathway.

Example 41 relates to the PIC of any of examples 34-40, and/or some other example herein, wherein the third signal pathway includes an X signal pathway and a Y signal pathway.

Example 42 relates to the PIC of example 41, and/or some other example herein, wherein the PIC further comprises: a third SOA positioned in the X signal pathway; and a fourth SOA positioned in the Y signal pathway.

Example 43 relates to an electronic device comprising: a first photonic integrated circuit (PIC) portion that includes a first transmit module, a first receive module, a first receive optical port, a first transmit optical port, a first reference optical port, and a first semiconductor optical amplifier (SOA) positioned in a first signal pathway between the first reference optical port and the first transmit module; and a second PIC portion that includes a second transmit module, a second receive module, a second receive optical port, a second transmit optical port, and a second SOA positioned in a second signal pathway between the second transmit module and the second transmit optical port.

Example 44 relates to the electronic device of example 43, and/or some other example herein, wherein the first PIC portion and the second PIC portion are on a same substrate as each other.

Example 45 relates to the electronic device of any of examples 43-44, and/or some other example herein, wherein the first reference optical port and the second reference optical port are communicatively coupled with a multimode interferometer (MMI).

Example 46 relates to the electronic device of example 45, and/or some other example herein, wherein the MMI is positioned in a third signal pathway between a third reference optical port and the first reference optical port, and wherein the MMI is further positioned in a fourth signal pathway between the third reference optical port and the second reference optical port.

Example 47 relates to the electronic device of any of examples 43-44, and/or some other example herein, wherein the first reference optical port and the second reference optical port are communicatively coupled with a demultiplexer configured to: demultiplex a plurality of reference optical signals signal to generate a first reference optical signal and a second reference optical signal; output the first reference optical signal to the first reference optical port; and output the second reference optical signal to the second reference optical port.

Example 48 relates to an electronic device comprising: a processor; and a photonic integrated circuit (PIC) communicatively coupled with the processor, wherein the PIC includes: a substrate; a reference optical port to receive a reference optical signal; a transmit module positioned on the substrate, the transmit module to receive a first data signal from the processor and output, based on the first data signal and the reference optical signal, a first optical signal to a transmit optical port of the PIC; a receive module positioned on the substrate, the receive module to receive a second optical signal from a receive optical port of the PIC and output, based on the second optical signal and the reference optical signal, a second data signal to the processor; and a first semiconductor optical amplifier (SOA) positioned on the substrate, wherein the first SOA is in a first signal pathway between the reference optical port and the transmit module.

Example 49 relates to the electronic device of example 48, and/or some other example herein, wherein the PIC further includes a second SOA in a second signal pathway between the reference optical port and the receive module.

Example 50 relates to the electronic device of example 49, and/or some other example herein, wherein the PIC further includes a power switch in the first signal pathway and the second signal pathway, wherein the power switch is configured to: receive the reference optical signal; output, to the transmit module via the first signal pathway, at least a first portion of the reference optical signal; and output, to the receive module via the second signal pathway, at least a second portion of the reference optical signal.

Example 51 relates to the electronic device of example 50, and/or some other example herein, wherein the PIC further includes a test laser coupled with an input of the power switch.

Example 52 relates to the electronic device of any of examples 48-51, and/or some other example herein, wherein the transmit module is to output the first optical signal to the transmit optical port via a third signal pathway between the transmit module and the transmit optical port and a fourth signal pathway between the transmit module and the transmit optical port.

Example 53 relates to the electronic device of example 52, and/or some other example herein, wherein the PIC further comprises: a third SOA in the third signal pathway; and a fourth SOA in the fourth signal pathway.

Example Z01 may include an apparatus comprising means to perform one or more elements of a method described in or related to any of examples herein, or any other method or process described herein.

Example Z02 may include an apparatus comprising logic, modules, or circuitry to perform one or more elements of a method described in or related to any of examples herein, or any other method or process described herein.

Example Z03 may include a method, technique, or process as described in or related to any of examples herein, or portions or parts thereof.

Example Z04 may include a signal as described in or related to any of examples herein, or portions or parts thereof.

1. A photonic integrated circuit (PIC) comprising:
a transmit module positioned on a substrate of the PIC;
a receive module positioned on the substrate;
a reference optical port communicatively coupled with the transmit module by a first signal pathway, wherein the reference optical port is further communicatively coupled with the receive module by a second signal pathway;
a transmit optical port communicatively coupled with the transmit module by a third signal pathway, wherein the transmit optical port is configured to transmit a first optical signal from the PIC;
a receive optical port communicatively coupled with the receive module by a fourth signal pathway, wherein the receive optical port is configured to receive a second optical signal; and
a first semiconductor optical amplifier (SOA) positioned on the substrate, wherein the first SOA is in the first signal pathway.

2. The PIC of claim 1, wherein the receive module includes an intradyne coherent receiver (ICR).

3. The PIC of claim 1, wherein the transmit module includes a dual polarization (DP) in-phase quadrature (IQ) modulator.

4. The PIC of claim 1, further comprising a power switch in the first and second signal pathways, wherein the power switch is to receive as input an reference optical signal from the reference optical port, and wherein the power switch is further to output at least a portion of the reference optical signal to the first signal pathway or the second signal pathway.

5. The PIC of claim 4, wherein the first SOA is in the first signal pathway between the power switch and the transmit module.

6. The PIC of claim 4, wherein the PIC further comprises a test laser configured to output a test optical signal to the power switch.

7. The PIC of claim 1, wherein the PIC further comprises a second SOA positioned on the substrate, wherein the second SOA is in the second signal pathway.

8. The PIC of claim 1, wherein the third signal pathway includes an X signal pathway and a Y signal pathway.

9. The PIC of claim 8, wherein the PIC further comprises:
a third SOA positioned in the X signal pathway; and
a fourth SOA positioned in the Y signal pathway.

10. An electronic device comprising:
a first photonic integrated circuit (PIC) portion that includes a first transmit module, a first receive module, a first receive optical port, a first transmit optical port, a first reference optical port, and a first semiconductor optical amplifier (SOA) positioned in a first signal pathway between the first reference optical port and the first transmit module; and
a second PIC portion that includes a second transmit module, a second receive module, a second receive optical port, a second transmit optical port, and a second SOA positioned in a second signal pathway between the second transmit module and the second transmit optical port.

11. The electronic device of claim 10, wherein the first PIC portion and the second PIC portion are on a same substrate as each other.

12. The electronic device of claim 10, wherein the first reference optical port and the second reference optical port are communicatively coupled with a multimode interferometer (MMI).

13. The electronic device of claim 12, wherein the MMI is positioned in a third signal pathway between a third reference optical port and the first reference optical port, and wherein the MMI is further positioned in a fourth signal pathway between the third reference optical port and the second reference optical port.

14. The electronic device of claim 10, wherein the first reference optical port and the second reference optical port are communicatively coupled with a demultiplexer configured to:
demultiplex a plurality of reference optical signals signal to generate a first reference optical signal and a second reference optical signal;
output the first reference optical signal to the first reference optical port; and
output the second reference optical signal to the second reference optical port.

15. An electronic device comprising:
a processor; and
a photonic integrated circuit (PIC) communicatively coupled with the processor, wherein the PIC includes:
a substrate;
a reference optical port to receive a reference optical signal;
a transmit module positioned on the substrate, the transmit module to receive a first data signal from the processor and output, based on the first data signal and the reference optical signal, a first optical signal to a transmit optical port of the PIC;
a receive module positioned on the substrate, the receive module to receive a second optical signal from a receive optical port of the PIC and output, based on the second optical signal and the reference optical signal, a second data signal to the processor; and
a first semiconductor optical amplifier (SOA) positioned on the substrate, wherein the first SOA is in a first signal pathway between the reference optical port and the transmit module.

16. The electronic device of claim 15, wherein the PIC further includes a second SOA in a second signal pathway between the reference optical port and the receive module.

17. The electronic device of claim 16, wherein the PIC further includes a power switch in the first signal pathway and the second signal pathway, wherein the power switch is configured to:
receive the reference optical signal;
output, to the transmit module via the first signal pathway, at least a first portion of the reference optical signal; and
output, to the receive module via the second signal pathway, at least a second portion of the reference optical signal.

18. The electronic device of claim 17, wherein the PIC further includes a test laser coupled with an input of the power switch.

19. The electronic device of claim 15, wherein the transmit module is to output the first optical signal to the transmit optical port via a third signal pathway between the transmit module and the transmit optical port and a fourth signal pathway between the transmit module and the transmit optical port.

20. The electronic device of claim 19, wherein the PIC further comprises:
a third SOA in the third signal pathway; and
a fourth SOA in the fourth signal pathway.
